(19) United States
(12) Patent Application Publication
(10) Pub. No.: US 2017/0122989 A1
(43) Pub. Date: May 4, 2017

(54) Method for Operating an Energy Consumption Metering System and Energy Consumption Metering System

(71) Applicant: Global Design Corporation Ltd., Wanchai (HK)

(72) Inventor: Yung Fai Ho, Hong Kong (HK)

(21) Appl. No.: 14/928,771

(22) Filed: Oct. 30, 2015

(51) Int. Cl. G01R 21/133; G01R 35/00; G01R 22/00

(52) U.S. Cl. CPC G01R 21/1333; G01R 22/00; G01R 35/005

(57) ABSTRACT

A method for operating an energy consumption metering system is provided. The method includes determining a first value of energy consumption at a central supply point by a first energy consumption metering device, and determining a second value of energy consumption of a sub-location of the central supply point by a second energy consumption metering device. A deviation of the first value and the second value is determined and based on the determined deviation, calibration data for calibrating at least one of the first and the second energy consumption metering device is determined.

### TECHNICAL FIELD

The present invention relates generally to metering systems, and in particular embodiments to methods for operating an energy consumption metering system and energy consumption metering systems.

### BACKGROUND

In conventional energy distribution networks, the energy consumption of a site is typically measured at a central supply point, e.g., between a supply line of the energy supplier and the first distribution panel of a given site, for example a single building or a distinct part of a building such as an apartment or the like. In this way, all electrical energy consumed at that particular site can be measured, irrespective of the electrical distribution system of the given site.

The energy consumption measured at such a central supply point is usually used by the utility provider for billing purposes. Thus, at the end of a billing period such as a month or year, the utility provider usually prepares a utility bill based on the measured total consumption and provides it to the site manager or owner. Based on the provided utility bill, a site manager or owner can then determine whether he or she has stayed within a desirable energy budget or has exceeded it.

Such a conventional approach is sufficient for billing purposes. However, in times of high energy prices and a focus on energy efficiency, the data available in such a conventional scheme is insufficient in order to maintain a control over how the energy is actually consumed within a given site and also in order to estimate, at any given time, whether given energy targets will be met.

In addition to metering devices installed at a central supply point, individual metering devices are known. For example, an individual metering device may be plugged into a socket and supply energy to an individual electricity consumer, such as an electrical appliance. Such energy metering devices allow to measure the energy consumption of a particular appliance at a given location. However, such data is only available locally at the individual metering device. Thus, at least in sites comprising a relatively large number of electrical appliances and other electricity consumers, the use of such metering devices is both expensive and time consuming, if a building manager or owner wants to obtain a reasonably complete picture of the energy consumption of the site to be monitored.

Accordingly, there is a need for energy consumption metering systems and associated methods for their operation that allow a comparison of the amount of energy consumed at the central supply point with the amount of energy consumed at sub-locations of the central supply point.

### SUMMARY

According to one aspect of the invention, a method for operating an energy consumption metering system is provided. The method comprises determining a first value of energy consumption at a central supply point by a first energy consumption metering device, and determining a second value of energy consumption of a sub-location of the central supply point by a second energy consumption metering device. A deviation of the first value and the second value is determined and based on the determined deviation, calibration data for calibrating at least one of the first and the second energy consumption metering device is determined.

According to another aspect of the present invention, a method for operating an energy consumption metering system is provided, which comprises determining a first value of energy consumption at a central supply point by a first energy consumption metering device. The method further includes determining a respective second value of energy consumption of each of a multitude of sub-locations of the central supply point by a multitude of second energy consumption metering devices. The determined values of the multitude of second energy consumption metering devices are summed to an aggregated value. A deviation of the first value and the aggregated value is determined and based on the determined deviation, calibration data for calibrating each energy consumption metering device of the multitude of second energy consumption metering devices is determined and/or calibration data for calibrating the first energy consumption metering device is determined.

According to a third aspect, an energy consumption metering system is provided. The system comprises a first energy consumption metering device for determining a first value of energy consumption at a central supply point. The system comprises a second energy consumption metering device for determining a second value of energy consumption of the sub-location of the central supply point. The system comprises a calibration device, which is configured to determine a deviation of the first value and the second value. The calibration device is further configured to determine calibration data for calibrating at least one of the first and the second energy consumption metering device based on the determined deviation.

According to a fourth aspect, an energy consumption metering system is provided. The system comprises a first energy consumption metering device for determining a first value of energy consumption at a central supply point. The system comprises a multitude of second energy consumption metering devices for determining respective second values of energy consumption of sub-locations of the central supply point. The system comprises a calibration device, which is configured to determine a deviation of the first value and a sum of the second values. The calibration device is further configured to determined calibration data for calibrating each energy consumption metering device of the multitude of second energy consumption metering devices and/or to determine calibration data for calibrating the first energy consumption metering device. The respective calibration data is determined based on the determined deviation.

The described methods and systems enable a more accurate comparison of the amount of energy determined at the central supply point and the amount of energy determined at the sub-locations. For example, the methods and systems allow a more detailed and accurate breakdown of the energy costs to the sub-locations.

### BRIEF DESCRIPTION OF THE DRAWINGS

Various embodiments of the present invention will be described with reference to the attached drawings.

FIG. 1 shows a schematic diagram of an energy consumption metering system; and

FIG. 2 shows a flowchart of an operation method for an energy consumption metering system.

### DETAILED DESCRIPTION OF ILLUSTRATIVE EMBODIMENTS

Embodiments of the present invention relate to methods for operating energy consumption metering systems. In various embodiments, the present invention relates to a method for operating an energy consumption metering system which is capable of determining electrical loads on a per circuit basis. Embodiments of the present invention further relate to energy consumption metering systems, in particular to an energy consumption metering system capable of determining electrical loads on a per circuit basis.

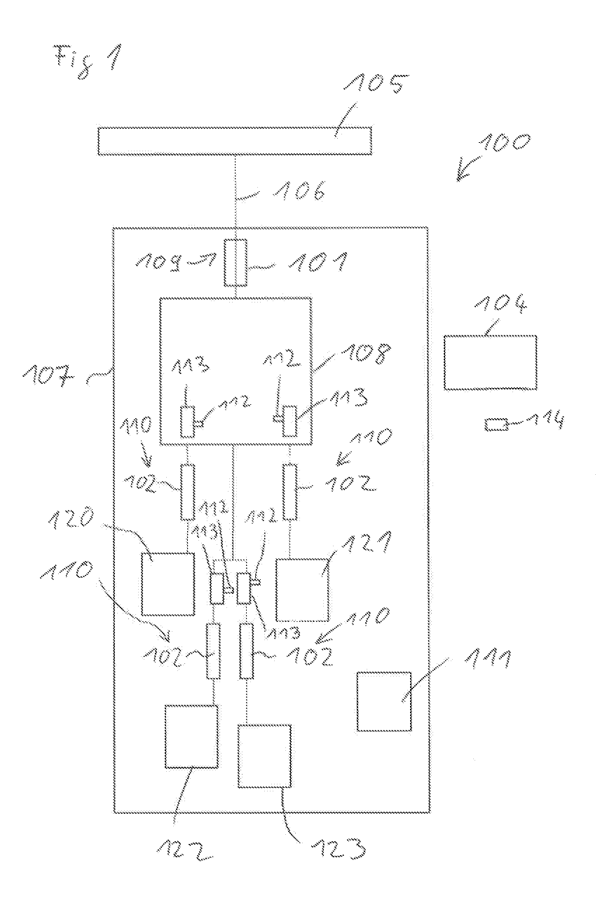

FIG. 1 shows a schematic diagram of an energy consumption metering system 100 in accordance with an embodiment of the present invention.

The system 100 comprises a first energy consumption metering device 100 and/or second energy consumption metering devices 102. Of course, in other embodiments, the system 100 may comprise less than 4 second energy consumption metering devices 102, for example one, two or three second energy consumption metering devices 102. Of course, in other embodiments, the system 100 may comprise more than four second energy consumption metering devices 102, for example five or more second energy consumption metering devices 102.

The first energy consumption metering device 101 is arranged at a main supply line 106. The supply line 106 is a supply line that connects a side 107 to an energy supplier 105. The site 107 may be an apartment or a house. The first energy consumption metering device 101 allows a measurement of the energy consumption of the whole site 107 at a central supply point 109, e.g. between the energy supplier 105 and a first distribution panel 108 of the site 107. In this way, all electrical energy consumed at the site 107 is measured, irrespective of the electrical distribution system of the given site.

The second energy consumption metering devices 102 are arranged downstream of the distribution panel 108. For example, one of the second energy consumption metering devices 102 measures an energy consumption between the distribution panel 108 and a first electric load 120. Another of the second energy consumption metering devices 102 may be arranged between the distribution panel 108 and a further distribution panel (not explicitly shown).

Within the monitored site 107, the energy supplied by the energy supplier 105 is distributed by a number of distribution panels. Typically, the energy provided to any specific end-point within the site 107 to be monitored is provided via at least one distribution panel 108 and protected by at least one circuit breaker 113. Attention is drawn to the fact that the monitored site 107 may contain tens, hundreds or even thousands of distribution panels and circuit-breakers.

In accordance with the described embodiment, the site 107 has four electric loads 120, 121, 122 and 123. Of course, in other embodiments there is a different of electric loads, especially more than four electric loads. By way of example, the first electric load is a power plug, the second electric load is lighting and the third and fourth electric loads are air-conditioning.

A second energy consumption metering device 102 is arranged between each load 120, 121, 122 and 123 and the distribution panel 108. The second energy consumption metering device 102 is configured to measure energy consumption of a respective sub-location 110 downstream of the central supply point 109. For example, the sub-location 110 is a room or another subunit of the site 107. The sub-location 110 may also be specified by connected loads, e.g. different loads in one room of the site 107. The second energy consumption metering device 102 is configured to determine an energy consumption of, e.g., a particular circuit or electric device of the sub-location 110. For example, energy consumption in different rooms of the site 107 may be determined.

The second energy consumption metering device 102 may be any kind of so-called smart metering device that is able to measure the energy consumption of the sub-location 110. For example the energy consumption is measured at a circuit level, for example for each circuit breaker 113. A sensor 112 is fitted to each one of the circuit breakers 113 to obtain load information for each individual circuit. For example, the sensors 112 are configured for sensing the strength of a magnetic field in the area of the respective circuit breaker 113. In a different embodiment, the sensors 112 may be associated with individual appliances, groups of circuit-breakers, distribution panels or any other distinct part of the energy distribution network within the site to be monitored.

Attention is drawn to the fact that the present invention is not restricted to the specific measuring system disclosed in FIG. 1. For the purpose of the present invention, it is sufficient to provide relatively fine-grained granular-level energy consumption values for further analysis as detailed below. Such data may also be obtained by advanced data analysis of data provided by one or a few sensors associated with larger parts of a monitored site, rather than by a large number of sensors associated with individual circuits or energy consuming devices.

A calibration device 104 is coupled with the first energy consumption metering device 101 and the multitude of second energy consumption metering devices 102. In particular, the sensors 112, and first and second energy consumption metering devices 101 and 102 as well as the calibration device 104 are connected by a local area network.

The calibration device 104 is configured to obtain the energy consumption data that is determined by the first and the second energy consumption metering devices 101 and 102. For example, the calibration device 104 is arranged at the side 107. According to further embodiments, the calibration device 104 is not present at the side 107, but may be implemented as a cloud-based web service by a utility provider, e.g. by the energy supplier 105 or another service provider.

The calibration device 104 is connected to a database 114. For example, the database 114 is a database of a cloud service arranged in a data network, in particular in the internet (not shown). According to further embodiments, the database 114 is included in the calibration device 104, e.g. at the side 107.

In accordance with the described embodiment, the system 100 comprises a user interface facility 111. The user interface facility 111 is coupled to the calibration device 104 and/or the energy consumption metering devices 101 and 102. The user interface facility 111 is especially configured to visualize and display energy consumption at the central supply point 109 and the sub-locations 110 and the further information, for example, billing information. For example, the user interface facility 111 is connected to the cloud-based calibration device 104 via the internet.

The first energy consumption metering device 101 at the supply line 106 is at revenue grade level for billing purpose based on the amount of usage determined by the first energy consumption metering device 101. The second energy consumption metering devices 102 may have different accuracy and tolerance to their technical competence and hardware capability. Therefore, the sum of the consumption data measured by the second energy consumption metering devices 102 on a user level may be different to the data from the first energy consumption metering device 101.

The deviation between the first energy consumption metering device 101 and the sum of the second energy consumption metering devices 102 may be between 0.5% and 30%. The system 100, especially the calibration device 104, is arranged to determine that deviation and to determine calibration data such that the energy consumption metering devices 101 and 102 may be calibrated to avoid the deviation between the first energy consumption metering device 101 and the second energy consumption metering devices 102. A method for calibrating in accordance with an embodiment is described in the following.

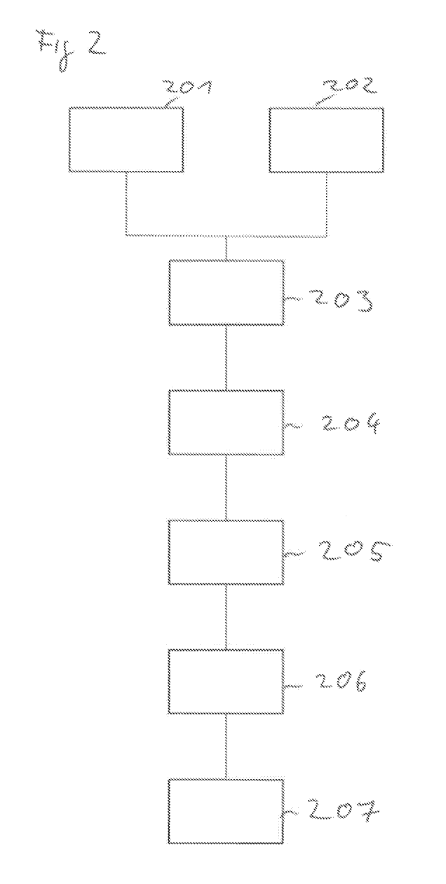

FIG. 2 shows steps performed for calibrating the first energy consumption metering device 101 and/or the second energy consumption metering devices 102 according to an embodiment.

In a first step 201 a first value of the energy consumption at the central supply point 109 is obtained by the first energy consumption metering device 101.

In step 202 energy consumption of each sub-location 110 is obtained by the corresponding second energy consumption metering devices 102. The energy consumption value at the central point and at the sub-locations 110 are determined at the same time or for the same period.

In step 203 the multitude of energy consumption values of the multitude of second energy consumption metering devices 102 is summed up to an aggregated value. In the case when only one single second energy consumption metering device 102 is provided, step 203 may be omitted.

In step 204 a deviation of the first value and the aggregated value is determined. For example, the deviation is determined by subtracting the value of the first energy consumption metering device 101 from the aggregated value. Of course, there are other ways to determine the deviation, for example by subtracting the aggregated value from the value of the first energy consumption metering device 101.

In step 205 calibration data is determined depending on the determined deviation of step 204. For example, the deviation is divided by a number of the second energy consumption metering devices 102 to get a proportional deviation. According to further embodiments, a ratio of the first value and the aggregated value is determined.

In step 206, the first energy consumption metering device 101 and/or each of the second energy consumption metering devices 102 is calibrated depending on the calibration data determined in step 205. According to the first method, the proportional deviation is added to each value of each of the energy consumption metering devices 102 to get calibrated values of the second energy consumption metering devices 102. According to the second method, the ratio of the first value and the aggregated value is multiplied with the value of the first energy consumption metering device 101 to get a converted value of the first energy consumption metering device 101. Further methods of calibrating and converting the values of the first and/or second energy consumption metering devices are applicable such that the deviation of the calibrated/converted values is zero.

The method may executed on the cloud service and in real time. The calibration data and/or the consumption data may be stored in the database 114 of the cloud service.

In an optional step 207, the deviation and/or the calibration data is visualized and displayed on the user interface facility 111, for example on a display of a portable device such as a smart phone.

According to an example, the user can see the total consumption from the first energy consumption metering device 101 and also see the breakdown consumption from the second energy consumption metering devices 102. According to embodiments, the second energy consumption metering devices 102 are parts of a combined energy consumption metering device. In an ideal scenario, the consumption value of the first metering device 101 is the same as the sum of the consumption values of the second metering devices 102. However, in reality, the first and the second energy consumption metering devices 101 and 102 are made from different accuracy standards so that the values may come out differently.

For example, the consumption value of the first energy consumption metering device 101 is 100 kWh. In the example, each consumption value of each of the second energy consumption metering devices 102 is 23 kWh. The sum of the values of the second energy consumption metering devices 102 is 92 kWh which results in a deviation of 8 kWh to the value of the first energy consumption metering device 101. Accordingly, the user does not get an accurate reading from the second energy consumption metering devices 102 as a breakdown while the first energy consumption metering device 101 is used for billing purposes and therefore may be used as the reference.

To calibrate the second energy consumption metering device 102, the deviation of 8 kWh is divided on the four second energy consumption metering devices 102. Accordingly, 2 kWh are added to the value of each of the second energy consumption metering devices 102 such that the converted values become 25 kWh. The sum of the converted values of the second energy consumption metering devices 102 becomes 100 kWh such that the deviation between the converted values of the second energy consumption metering device 102 and the first energy consumption metering device 101 becomes zero.

Of course, it is possible also to calibrate the first energy consumption metering device 101 dependent on the values of energy consumption of one or the multitude of the second energy consumption metering devices 102. For example, if the second energy consumption metering devices 102 are more accurate than the first energy consumption metering device 101, then the values of energy consumption of the second energy consumption metering device or the calibration data respectively is used to calibrate the first energy consumption metering device 101 to offset the deviation.

Because the converted values of the second energy consumption metering device 102 and the value of the first energy consumption metering device 101 are the same after the calibration, it is easy for the user to compare how much money they are actually spending on their consumption because the data that is used for billing purposes is the same as the data for the sub-locations 110. Further, it is possible to combine modern second energy consumption metering devices 102 with older first energy consumption metering devices 101 whose accuracy is not as good as the accuracy of the second energy consumption metering device 102.

With the energy metering system 100 it is possible to capture both the consumption value of the first energy consumption metering device 101 and the second energy consumption metering devices 102 which are sub-meters of the first metering device 101. For example, the second energy consumption metering devices' data gets calibrated and converted depending on the data of the first energy consumption metering device 101. However, the calibration can be either way. For example, the first energy consumption metering device's data gets calibrated and converted depending on the data of the second energy consumption metering devices 102. Accordingly, the user can see the consumption breakdown of the site 107 with reference to the accuracy of the first energy consumption metering device 101. On the other hand, the first energy consumption metering device 101 can take the reference reading from one or more of the second energy consumption metering devices 102 to tune up the accuracy. For example, in the site 107, it is possible to use the consumption data obtained by the second energy consumption metering devices 102 to calibrate and convert the values from the first energy consumption metering device 101. For example, the values are sent through the internet network.

With the energy metering system 100 the user has a much more accurate figure of the energy consumption of the sub-locations 110. The user is able to know the real charge by sub-location 110 of their appliance consumption. It is possible to provide a consumption breakdown for the user in alignment with the bill that is based on the first energy consumption metering device 101. It is easy to promote energy saving by behaviour changes of usage because the consumption breakdown cost is in line with the charge for the whole side 107.

What is claimed is:

1. A method for operating an energy consumption metering system, the method comprising:
determining a first value of energy consumption at a central supply point by a first energy consumption metering device;
determining a second value of energy consumption of a sub-location of the central supply point by a second energy consumption metering device;
determining a deviation of the first value and the second value; and
based on the determined deviation, determining calibration data for calibrating at least one of the first and the second energy consumption metering device.

2. The method according to claim 1, comprising:
based on the determined calibration data, converting the first value and the second value, such that the deviation becomes zero.

3. The method according to claim 1, comprising:
based on the determined calibration data, converting only one of the first value or the second value, such that the second value becomes equal to the first value after the converting.

4. The method according to claim 1, further comprising:
storing the determined calibration data in a database of a cloud service.

5. The method according to claim 1, further comprising:
based on previously determined calibration data, converting the first value and/or the second value prior to determining the deviation of the first value and the second value, wherein determining a deviation of the first value and the second value comprises: determining a deviation of the converted first value and the converted second value.

6. The method according to claim 1, wherein determining the second value of energy consumption comprises:
determining the second value of energy consumption by a sensor arranged in proximity to a circuit breaker associated with a corresponding electrical circuit, the sensor being configured to provide a specific consumption value of the electrical circuit.

7. The method according to claim 1, further comprising:
notifying a user about the determined deviation via a user interface facility.

8. A method for operating an energy consumption metering system, the method comprising:
determining a first value of energy consumption at a central supply point by a first energy consumption metering device;
determining a respective second value of energy consumption of each of a multitude of sub-locations of the central supply point by a multitude of second energy consumption metering devices;
summing up the determined values of the multitude of second energy consumption metering devices to an aggregated value;
determining a deviation of the first value and the aggregated value; and
based on the determined deviation, determining calibration data for calibrating each energy consumption metering device of the multitude of second energy consumption metering devices and/or determining calibration data for calibrating the first energy consumption metering device.

9. The method according to claim 8, comprising:
based on the determined calibration data, converting the first value and/or at least one of the second values, such that the deviation becomes zero.

10. The method according to claim 8, comprising:
based on the determined calibration data, converting each of the second values and adding up the converted second values to a converted aggregated value, such that the deviation of the first value and the converted aggregated value becomes zero.

11. The method according to claim 10, wherein determining the calibration data comprises:
determining a number of the second energy consumption metering devices; and
dividing the determined deviation by the determined number to determine the calibration data.

12. The method according to claim 8, wherein determining the calibration data comprises:
determining a ratio of the first value and the aggregated value.

13. The method according to claim 8, further comprising:
storing the determined calibration data in a database of a cloud service.

14. The method according to claim 8, further comprising:
based on previously determined calibration data, converting the first and/or the second value prior to determining the deviation of the first value and the second value, wherein determining a deviation of the first value and the second value comprises: determining a deviation of the converted first value and the converted second value.

15. The method according to claim 8, wherein determining the second value of energy consumption comprises:
determining the second value of energy consumption by a sensor arranged in proximity to a circuit breaker associated with a corresponding electrical circuit, the sensor being configured to provide a specific consumption value of the electrical circuit.

16. The method according to claim 8, comprising:
notifying a user about the determined deviation via a user interface facility.

17. An energy consumption metering system comprising:
a first energy consumption metering device for determining a first value of energy consumption at a central supply point;
a second energy consumption metering device for determining a second value of energy consumption of a sub-location of the central supply point; and
a calibration device, the calibration device being configured to determine a deviation of the first value and the second value, and based on the determined deviation, to determine calibration data for calibrating at least one of the first and the second energy consumption metering devices.

18. The energy consumption metering system according to claim 17, wherein the first energy consumption metering device is configured to be arranged between a supply line of an energy supplier and a first distribution panel of the central supply point.

19. The energy consumption metering system according to claim 17, wherein the second energy consumption metering device is configured to be arranged subordinated to the first energy consumption metering device.

20. The energy consumption metering system according to claim 17, wherein the second energy consumption metering device comprises a sensor configured to be arranged in proximity to a circuit breaker associated with a corresponding electrical circuit, the sensor being configured to provide a specific consumption value of the electrical circuit.

21. The energy consumption metering system according to claim 17, further comprising a user interface facility to notify a user about the determined deviation.

22. An energy consumption metering system comprising:
a first energy consumption metering device for determining a first value of energy consumption at a central supply point;
a multitude of second energy consumption metering devices for determining respective second values of energy consumption of sub-locations of the central supply point; and
a calibration device, the calibration device being configured to determine a deviation of the first value and a sum of the second values, and based on the determined deviation, to determine calibration data for calibrating each energy consumption metering device of the multitude of second energy consumption metering devices and/or to determine calibration data for calibrating the first energy consumption metering device.

23. The energy consumption metering system according to claim 22, wherein the first energy consumption metering device is configured to be arranged between a supply line of an energy supplier and a first distribution panel of the central supply point.

24. The energy consumption metering system according to claim 22, wherein the second energy consumption metering device is configured to be arranged subordinated to the first energy consumption metering device.

25. The energy consumption metering system according to claim 22, wherein the second energy consumption metering device comprises a sensor configured to be arranged in proximity to a circuit breaker associated with a corresponding electrical circuit, the sensor being configured to provide a specific consumption value of the electrical circuit.

26. The energy consumption metering system according to claim 22, further comprising a user interface facility to notify a user about the determined deviation.
